(19) United States
(12) Patent Application Publication
(10) Pub. No.: US 2007/0196979 A1
(43) Pub. Date: Aug. 23, 2007

(54) Flip chip in package using flexible and removable leadframe

(75) Inventors: Teck Tiong Tan, Singapore (SG); Hwee Seng Jimmy Chew, Singapore (SG); Kok Yeow Eddy Lim, Singapore (SG); Abd. Razak Bin Chichik, Singapore (SG); Kee Kwang Lau, Singapore (SG); Chuan Wei Wong, Singapore (SG)

Correspondence Address: CONLEY ROSE, P.C.;David A. Rose, P. O. BOX 3267, HOUSTON, TX, 77253-3267, US

(73) Assignee: Advanpack Solutions Pte Ltd, Singapore (SG)

(21) Appl. No.: 11/358,801

(22) Filed: Feb. 21, 2006

(51) Int. Cl. H01L 21/8242

(52) U.S. Cl. 438/253

(57) ABSTRACT

A method for forming semiconductor packages is disclosed. The method involves providing a support substrate and forming at least one conductive layer thereon. The method also includes coupling the at least one conductive layer to a support face of a film substrate for securing the at least one conductive layer to the support face and removing the support substrate from the at least one conductive layer. The at least one interconnector is adhered to the film substrate for forming an interposer. The method further involves bonding a integrated circuit chip to the at least one conductive layer of the interposer and disposing a compound over the support face to thereby encapsulate the integrated circuit chip and the least one conductive layer for forming an encapsulated package therefrom. Portions of the at least one conductive layer is then exposed by removing the film substrate from the encapsulated package.

### FIELD OF INVENTION

This invention relates generally to a method for forming a semiconductor package. In particular, it relates to a method for forming a conductive layer for connecting electrical terminals of an integrated circuit chip to circuitries on an electrical substrate or circuit board.

### BACKGROUND

As the functionality, speed and portability of consumer electronics improves, the need for more semiconductor devices to be packed into smaller spaces of an integrated circuit (IC) chip also increases. The latest cell phones not only provide voice communication but are also capable of receiving real-time information from the Internet. This demonstrates constantly improving functionality that causes the quantity of semiconductor devices formed on the IC chip to increase dramatically. Additionally, as the dimensional thickness of consumer electronics reduces, the demand for low profile components of the consumer electronics, such as a semiconductor package that contains the IC chip, also increases.

IC chips are typically connected to circuitries on an electrical substrate or circuit board via an interposer or leadframe. The leadframe is a metal conductor to which electrical terminals of the IC chips are connected. The distance or pitch between adjacent electrical terminals on the IC chips reduces as a result of more semiconductor devices being spatially integrated into smaller spaces of the IC chip. The IC chip is subsequently encapsulated together with portions of the leadframe using a compound to protect the IC chip against environmental elements and for forming a semiconductor package. Signal paths extending through the connections between the leadframe and the electrical terminals of the IC chips are usually spatially redistributed by the leadframe when the semiconductor package is eventually attached to the electrical substrate or circuit board.

Although conventional leadframes are used for producing semiconductor packages with a low profile, there is an existing lower limit as to how much the profile of the conventional leadframes can be reduced. Conventional leadframes are formed using a sheet of metal having a thickness of 120 to 250 micrometers (μm). Through the use of photolithography and etching processes, the conventional leadframes are fabricated from the sheet of metal. In order to reduce the profile of a semiconductor package, conventional leadframes are typically further etched for reducing the thickness thereof. However, undercutting may occur during etching which may adversely affects the reliability of the conventional leadframes. As a result, conventional leadframes are not suitable for producing semiconductor packages requiring a low profile and adaptation for fine pitch connections.

Additionally, the conventional leadframes are usually exteriorly coated with a layer of finishing, such as nickel palladium (NiPd). The layer of finishing replaces the need for solder plating that is necessary for connecting conventional leadframes to electrical substrates or circuit boards. However, the layer of finishing is not able to adhere sufficiently to the compound during the encapsulation of the conventional leadframes. This undesirably limits the reliability performance of the semiconductor package.

Therefore, there is clearly affirms a need for a method for forming a leadframe which can be suitably used for improving the reliability performance of semiconductor packages having a low profile and adapted for fine pitch connections.

### SUMMARY

A preferred embodiment of the invention disclosed herein relates to a method for forming a conductive layer that connects electrical terminals of an integrated circuit chip to circuitries of an electrical substrate or circuit board. Advantageously, the preferred embodiment of the invention provide a method for improving the reliability performance of semiconductor packages having a low profile and adapted for fine pitch connections.

Therefore, in accordance with one aspect of the invention, a method for forming a semiconductor package is disclosed. The method involves providing a support substrate and forming at least one conductive layer thereon. The method also includes coupling the at least one conductive layer to a support face of a film substrate for securing the at least one conductive layer to the support face and removing the support substrate from the at least one conductive layer. The at least one conductive layer is adhered to the film substrate for forming an interposer. The method further involves bonding an integrated circuit chip to the at least one conductive layer of the interposer and disposing a compound over the support face to thereby encapsulate the integrated circuit chip and the at least one conductive layer for forming an encapsulated package therefrom. Portions of the at least one conductive layer is then exposed by removing the film substrate from the encapsulated package.

### BRIEF DESCRIPTION OF THE DRAWINGS

A preferred embodiment of the invention is described hereinafter with reference to the drawings, in which:

FIG. 1 illustrates a flow diagram for forming an interposer according to an embodiment of the invention;

FIG. 2A is an extended flow diagram illustrating the coupling of an integrated circuit chip to the interposer according to the invention in FIG. 1;

FIG. 2B illustrates an encapsulated package comprising conductive structures with tapered sidewalls according to the embodiment of the invention in FIG. 1;

FIG. 3 shows an extended system flow diagram for forming a first semiconductor package according to a first application of the embodiment of the invention in FIG. 2A; and

FIG. 4 shows an extended system flow diagram for forming a second semiconductor package according to a second application of the embodiment of the invention in FIG. 2A.

### DETAILED DESCRIPTION

With reference to the drawings, a preferred embodiment of the invention is described hereinafter for addressing the need for a method for forming a conductive layer that connects electrical terminals of an integrated circuit (IC) chip to circuitries on an electrical substrate or circuit board. Conventional methods make use of metal sheets for forming the conductive layer and are not suitable for use in producing semiconductor packages that have low profiles and are adapted for fine pitch connections.

The method for forming the conductive layer according to one embodiment of the invention advantageously allows the formation of semiconductor packages with low profiles and which are adaptable for fine pitch connections. A further advantage resulting from the use of the method is that the performance reliability of semiconductor packages is improved.

For purposes of brevity and clarity, the description of the invention is hereinafter limited to applications related to forming a conductive layer for the formation of semiconductor packages. This however does not preclude embodiments of the invention from other areas of application for producing semiconductor packages with a low profile and which are adaptable for fine pitch connections. The functional and operational principles on which the embodiments of the invention are based remain the same throughout the various embodiments.

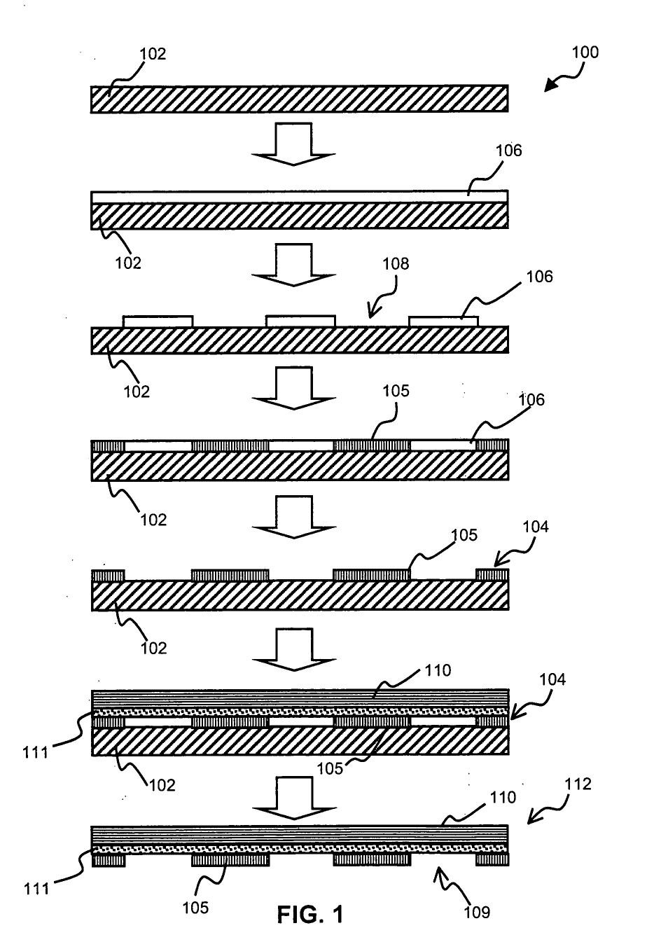

A preferred embodiment of the invention are described in greater detail hereinafter in accordance to FIGS. 1 to 4 of the drawings, wherein like elements are identified with like reference numerals.

With reference to FIG. 1, the preferred embodiment of the invention for a method 100 for forming a conductive layer 104 is shown. The initial step of the method 100 requires a support substrate 102 preferably made of an electrically conductive metal, for example steel. The support substrate 102 provides a surface on which the conductive layer 104 is formed. The method 100 also involves forming the conductive layer 104 using an electroplating process. The conductive layer 104 comprises conductive structures 105 that are used for connecting electrical terminals of an IC chip to the circuitries on an electrical substrate or a printed circuit board (PCB).

A layer of photoresist 106, preferably negative photoresist, is coated over the support substrate 102 for forming the conductive layer 104. The layer of photoresist 106 is exposed to radiation and developed by chemicals for creating openings 108 therein. These openings 108 define a layout for along which the conductive layer 104 is formed. These openings 108 spatially conform with a predetermined configuration for the conductive layer 104. The conductive layer 104 is preferably made of copper.

Thereafter, the support substrate 102 and the layer of photoresist 106 are submerged within a bath. The openings 108 are subsequently filled, using an electroplating process, for forming the conductive structures 105 of the conductive layer 104. The electroplating process preferably allows the conducting structures 105 to achieve a uniform thickness of approximately 30 micrometers (μm) to enable the conductive structures 105 to support fine pitch connections.

The electroplating process also facilitates deposition of additional conductive materials such as nickel (Ni), palladium (Pd) or gold (Au) in predetermined sections of each of the openings 108. A layer of finishing, such as NiPd, is therefore advantageously capable of being selectively formed on one or both ends of the conductive structures 105. In the preferred embodiment of the invention, the layer of finishing is preferably formed on one end of the conductive structure 105 distal to the support substrate 102.

After the conductive structures 105 of the conductive layer 104 are formed, the layer of photoresist 106 is removed. The conductive layer 104 is then coupled to a support face 109 of a film substrate 110. The film substrate 110 is preferably made from polyimide. The film substrate 110 comprises an adhesive layer 111 formed on the support face 109 thereof for coupling the film substrate 110 to the conductive layer 104. After the film substrate 110 is coupled to the conductive layer 104, the support substrate 102 is detached from the conductive layer 104 to thereby leave an interposer 112 comprising the conductive layer 104 and the film substrate 110. The film substrate 110 is then preferably secured to a holding structure (not shown), such as a frame, to facilitate handling thereof. The holding structure also stabilizes the interposer 112 during subsequent processing of the interposer 112.

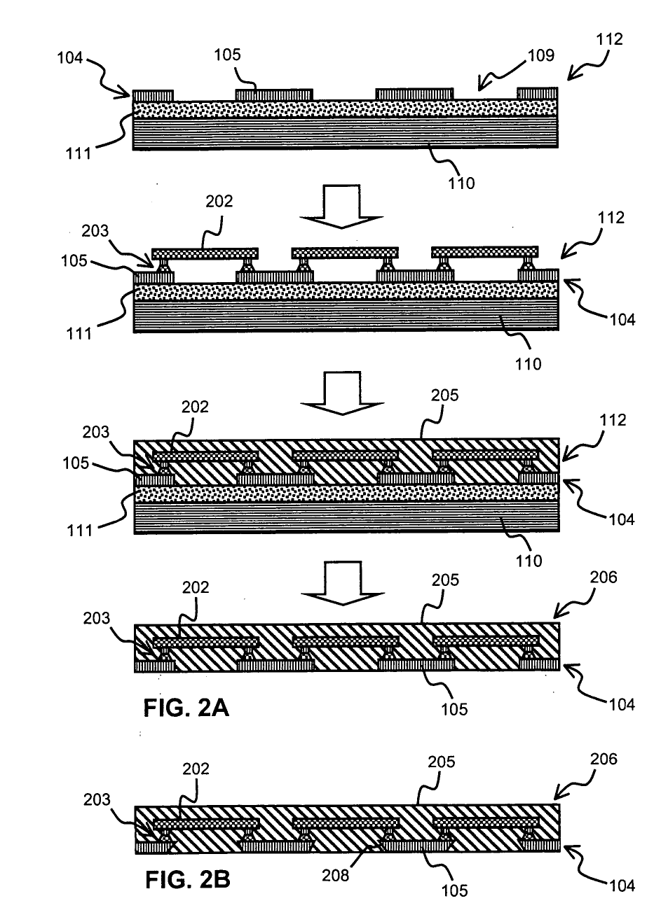

With reference to FIG. 2A, the interposer 112 is usable for forming a Quad Flat No-Lead (QFN) package or a Ball Grid Array (BGA) package. An IC chip 202, such as a flip chip, is bonded to the conductive layer 104 of the interposer 112. Pillar bumps 203 are preferably used for bonding the flip chip 202 to the interposer 112.

Subsequently, the flip chip 202 and the interposer 112 undergo a molding process. An encapsulating compound 205 is disposed over the support face 109 for encapsulating the flip chip 202 and the conductive layer 104 to thereby form an encapsulated package 206 therefrom. The encapsulating compound 205 is disposed on the conductive layer 104 without making contact with the layer of finishing that is formed on the conductive layer 104. This desirably improves adhesion between the encapsulating compound 205 and the interposer 112. The encapsulating compound 205 protects the flip chip 202 against environmental elements, such as dust particles. Following the molding process, the film substrate 110 is removed by first being heated and then being peeled away from the encapsulated package 206 to expose portions of the conductive layer 104.

FIG. 2B shows a preferred variation of the encapsulated package 206. Referring to FIG. 2B, sidewalls 208 of each of the conductive structures 105 converges while extending away from the flip chip 202 for providing each of the conductive structures 105 with a reverse-tapering dovetail shape. This enables each of the conductive structures 105 to structurally wedge onto the encapsulating compound 205 and substantially prevents decoupling of the conductive structures 105 from the encapsulating compound 205. The reverse-tapering dovetail shape of the sidewalls 208 is obtained by using negative photoresist during the formation of the conductive layer 104.

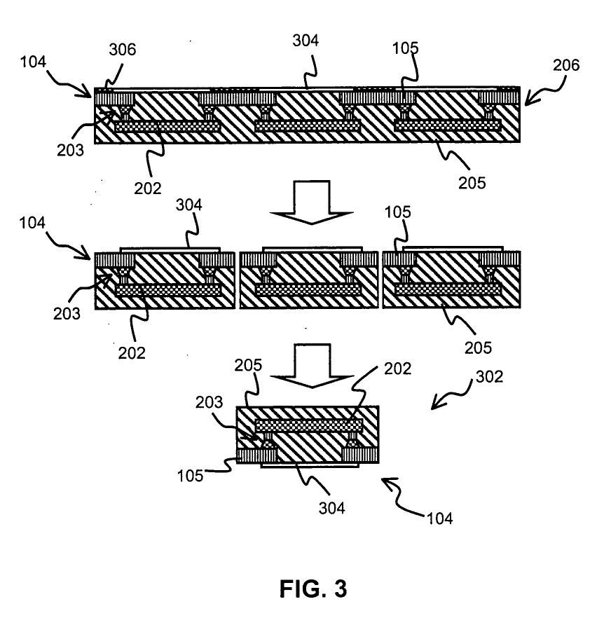

FIG. 3 illustrates a process using the encapsulated package 206 for forming a QFN package 302 according to a first application of the preferred embodiment of the invention. A layer of epoxy 304, with the aid of a stencil 306, is printed over one side of the encapsulated package 206 in a manner that only a predetermined portion of the conductive layer 104 is exposed thereafter. The stencil 306 therefore aids in outlining exposed portions of the conductive layer 104 whereat protection is required. The layer of epoxy 304 is however printed with a thickness of not more than 25 μm. After printing, the stencil 306 is removed and the encapsulated package 206 is singulated to form multiple QFN packages 302.

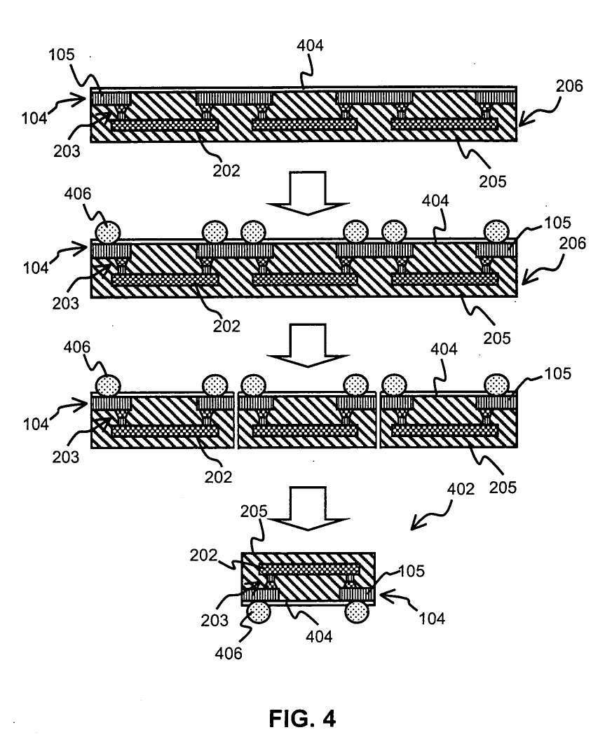

As shown in FIG. 4, the encapsulated package 206 is usable for forming a BGA package 402 according to a second application of the preferred embodiment of the invention. A protective layer 404, preferably a polymer flux, is disposed over the one side of the encapsulated package 206 having the exposed conductive layer 104. Thereafter, solder balls 406 are reflowed and bonded to the conductive layer 104. By reflowing the solder balls 406 with polymer flux, the bonding between the solder balls 406 and the conductive layer 104 is advantageously strengthened. After reflowing of the solder balls 406, the encapsulated package 206 is singulated to form multiple BGA packages.

In the foregoing manner, a method for forming a conductive layer that connects electrical terminals of an IC chip to circuitries on an electrical substrate or circuit board is disclosed. Although only a preferred of embodiment of the invention is disclosed, it becomes apparent to one skilled in the art in view of this disclosure that numerous changes and/or modification can be made without departing from the scope and spirit of the invention.

What is claimed is:

1. A method for forming semiconductor packages, comprising the steps of:
providing a support substrate;
forming at least one conductive layer on the support substrate;
coupling the at least one conductive layer to a support face of a film substrate for securing the at least one conductive layer to the support face;
removing the support substrate from the at least one conductive layer, the at least one conductive layer being adhered to the film substrate, the at least one conductive layer and the film substrate forming an interposer;
bonding an integrated circuit chip to the at least one conductive layer of the interposer;
disposing a compound over the support face to thereby encapsulate the integrated circuit chip and the at least one conductive layer for forming an encapsulated package therefrom; and
exposing portions of the at least one conductive layer by removing the film substrate from the encapsulated package.

2. The method as claimed in claim 1, further comprising the steps of:
coating a protective layer over the exposed portions of the at least one conductive layer; and
singulating the encapsulated interposer into semiconductor packages.

3. The method as claimed in claim 2, the step of coating a protective layer over the exposed portions of the at least one exposed conductive layer, further comprising the step of:
attaching solder balls to the encapsulated package.

4. The method as claimed in claim 2, the step of coating a protective layer over the exposed portions of the at least one conductive layer, further comprising the step of:
coating the protective layer over predefined areas of the exposed portions of the at least one conductive layer.

5. The method as claimed in claim 4, the step of coating the protective layer over predefined areas of the exposed portions of the at least one conductive layer, comprising the step of:
stencilling the protective layer for producing predefined areas of the exposed portions of the at least one conductive layer.

6. The method as claimed in claim 2, the step of coating a protective layer over the exposed portions of the at least one conductive layer, comprising the step of:
introducing epoxy-based flux for use as the protective layer.

7. The method as claimed in claim 1, the step of forming at least one conductive layer on the support substrate, further comprising the step of:
forming the at least one conductive layer having a plurality of conductive structures.

8. The method as claimed in claim 7, further comprising the step of:
forming the at least one conductive structures with sidewalls that converge when extending away from the integrated circuit chip.

9. The method as claimed in claim 8, further comprising the step of:
providing sidewalls with a reverse tapering dovetail shape.

10. The method as claimed in claim 1, the step of attaching a film substrate onto the at least one conductive layer, further comprising the step of:
introducing an adhesive layer on the film substrate for securing the at least one conductive layer to the film substrate.

11. The method as claimed in claim 1, further comprising the steps of:
attaching solder balls to the exposed portions of the at least one conductive layer; and
singulating the encapsulated package into Ball Grid Array (BGA) packages.

12. The method as claimed in claim 1, further comprising the steps of:
coating a protective layer over the exposing portions of the at least one conductive layer; and
singulating the encapsulated package into Quad Flat No-lead (QFN) packages.

13. A method for forming an interposer, comprising the steps of:
providing a support substrate;
forming at least one conductive layer having a plurality of conductive structures on the support substrate;
coupling the at least one conductive layer to a support face of a film substrate for securing the at least one conductive layer to the support face; and
removing the support substrate from the at least one conductive layer,
wherein the at least one conductive layer is adhered to the film substrate, and
wherein the at least one conductive layer and the film substrate form the interposer.

14. An interposer comprising:
a support substrate;
at least one conductive layer having a plurality of conductive structures formed on the support substrate; and
a film substrate having a support face for coupling the at least one conductive layer to the support face,
wherein the at least one conductive layer is adhered to the film substrate and the support substrate is removable from the at least one conductive layer.
